(19) United States
(12) Patent Application Publication
(10) Pub. No.: US 2009/0243063 A1
(43) Pub. Date: Oct. 1, 2009

(54) PACKAGING METHOD OF MICRO ELECTRO MECHANICAL SYSTEM DEVICE AND PACKAGE THEREOF

(76) Inventors: Jun-Bo Yoon, Daejeon (KR); Byung-Kee Lee, Daejeon (KR); Weon-Wi Jang, Daejeon (KR)

Correspondence Address: The Belles Group, P.C., 1518 Walnut Street, Suite 1706, Philadephia, PA, 19102, US

(21) Appl. No.: 12/404,743

(22) Filed: Mar. 16, 2009

(30) Foreign Application Priority Data
Mar. 26, 2008 (KR) 10-2008-0027837

(51) Int. Cl. H01L 23/02; H01L 21/50

(52) U.S. Cl. 257/678; 438/106; 257/E23.18; 257/E21.499

(57) ABSTRACT

Disclosed are a micro electro mechanical system (MEMS) device and a package thereof. The packaging method of a MEMS device comprises: sequentially forming a sacrificial layer, a support layer, and a block copolymer layer on a substrate on which the MEMS device is formed; self-assembling the block copolymer layer formed on the support layer; selectively etching a part of the self-assembled block copolymer layer to form a plurality of nano-pores; forming a plurality of etching holes in the support layer corresponding to the plurality of nano-pores using the block copolymer layer in which the plurality of nano-pores are formed as a mask; removing the sacrificial layer using the etching holes formed in the support layer; and forming a shielding layer on the support layer.

This application claims the benefit of Korean Patent Application No. 10-2008-0027837 filed on Mar. 26, 2008, which is hereby incorporated by reference.

### BACKGROUND OF THE INVENTION

1. Field of the Invention

The present invention relates to a packaging method of a micro electro mechanical system (MEMS) device and a package thereof.

2. Description of the Related Art

In general, MEMS devices have been applied in various fields such as optical communication, RF devices, and storage media using surface micromachining technology. Further, MEMS devices have been used in main parts such as a sensor of an information device or a printer head. Accordingly, there is a need for packaging protecting MEMS devices from physical or chemical environments so the MEMS devices have stability and reliability.

Packaging methods of the MEMS devices may be mainly classified into adhesion type and in-situ type.

FIG. 1 and FIG. 2 are views illustrating an adhesion type packaging method of a MEMS device.

Referring to FIG. 1, in the adhesion type packaging method of a MEMS device, a device substrate 100 and a packaging substrate 140 are aligned so that a first adhesion layer 120 formed on the device substrate faces a second adhesion layer 130 formed on lower edges of the packaging substrate 140.

Next, referring to FIG. 2, the device substrate 100 and the packaging substrate 140 are adhered thereto using the first adhesion layer 120 and the second adhesion layer 130. Thereafter, the MEMS device is packaged on the device substrate 100. In the adhesion type packaging method of a MEMS device, a number of substrates or wafers should be used so as to package the MEMS device. Further, since there is a need for an adhesion layer adhering between the substrates and an aligner aligning the substrates, it increases manufacturing costs.

FIG. 3 and FIG. 4 are views illustrating an in-situ type packaging method of an MEMS device.

Referring to FIG. 3, in the in-situ type packaging method of a MEMS device, a sacrificial layer 220 and a thin film layer 225 are sequentially formed on a substrate 200 on which a MEMS device 210 is formed. Next, etching holes 230 are formed in respective edges of the sacrificial layer 220 and the thin film layer 225 to remove the sacrificial layer 200 existing inside the thin film layer 225.

Thereafter, referring to FIG. 4, a shielding layer 240 is formed in an upper portion of the thin film layer 225 to seal an inside of the thin film layer 225, so that the MEMS device 210 is packaged.

In the in-situ type packaging method, in order to remove the sacrificial layer 240, the etching holes 230 are formed in the vicinity of edges of the MEMS device 210. In a case where the sacrificial layer 220 is removed using the etching holes 230, it takes a long time. Moreover, the MEMS device 210 can be physically and chemically damaged during removal thereof.

### SUMMARY OF THE INVENTION

The present invention has been made in view of the above problems, and it is an object of the present invention to provide a packaging method that may minimize physical or chemical damage of MEMS devices and reduce a time of a packaging process.

It is another object of the present invention to provide a package of MEMS devices manufactured by the packaging method according thereto.

In accordance with an exemplary embodiment of the present invention, there is provided a packaging method of a micro electro mechanical system (MEMS) device comprising: sequentially forming a sacrificial layer, a support layer, and a block copolymer layer on a substrate on which the micro electro mechanical system device is formed; (b) self-assembling the block copolymer layer formed on the support layer; (c) selectively etching a part of the self-assembled block copolymer layer to form a plurality of nano-pores; (d) forming a plurality of etching holes in the support layer corresponding to the plurality of nano-pores using the block copolymer layer in which the plurality of nano-pores are formed as a mask; (e) removing the sacrificial layer using the etching holes formed in the support layer; and (f) forming a shielding layer on the support layer.

Preferably, the packaging method includes removing the block copolymer layer in which the plurality of nano-pores are formed after step (d).

Preferably, the sacrificial layer formed to comprise material consisting of metal or polymer.

Preferably, the support layer is formed to comprise at least one of a silicon oxide, a silicon nitride, and a silicon carbide.

Preferably, step (b) comprises: spin-coating the block copolymer layer formed on the support layer; and heating treat the spin-coated block copolymer layer to self-assemble the block copolymer layer so that a plurality of assembled monomers with a cylindrical structure are formed.

Preferably, step (c) comprises: patterning a photo-resist to expose a partial region of the block copolymer layer; irradiating light on the exposed block copolymer layer using the photo-resist as a mask; and

removing the plurality of assembled monomers with the cylindrical structure from the block copolymer layer to the light is irradiated.

Preferably, the shielding layer is formed to comprise at least one of a silicon oxide, a silicon nitride, and a silicon carbide.

Preferably, the shielding layer is formed to comprise at least one of benzocyclobutene (BCB) and polyimide.

In accordance with another aspect of the present invention, there is provided a package of a micro electro mechanical system (MEMS) device comprising: a micro electro mechanical system device formed on a substrate; a support layer being spaced apart from the micro electro mechanical system device formed on the substrate to enclose the micro electro mechanical system device wherein a plurality of etching holes are formed in an upper portion of the support layer; and a shielding layer formed to enclose the support layer.

Preferably, the support layer comprises at least one of a silicon oxide, a silicon nitride, and a silicon carbide.

More preferably, the shielding layer comprises at least one of a silicon oxide, a silicon nitride, and a silicon carbide.

Most preferably, the shielding layer comprises at least one of benzocyclobutene (BCB) and polyimide.

In the present invention, a removal time of a sacrificial layer may be reduced and physical or chemical damage of MEMS devices may be minimized by forming an etching hole for removing the sacrificial layer in an upper part of the MEMS devices using a self assembled nano-structure of a block copolymer layer to remove the sacrificial layer.

### BRIEF DESCRIPTION OF THE DRAWINGS

The objects, features and advantages of the present invention will be more apparent from the following detailed description in conjunction with the accompanying drawings, in which:

FIG. 1 and FIG. 2 are views illustrating an adhesion type packaging method of an MEMS device;

FIG. 3 and FIG. 4 are views illustrating an in-situ type packaging method of a MEMS device;

FIG. 5 to FIG. 9 are views illustrating a method for manufacturing an MEMS switch device in accordance with an embodiment of the present invention;

FIG. 10 to FIG. 17 are views illustrating a packaging method of a MEMS switch device in accordance with an embodiment of the present invention; and

FIG. 18 is a view illustrating a plurality of nano-pores formed on a block copolymer layer in accordance with an embodiment of the present invention.

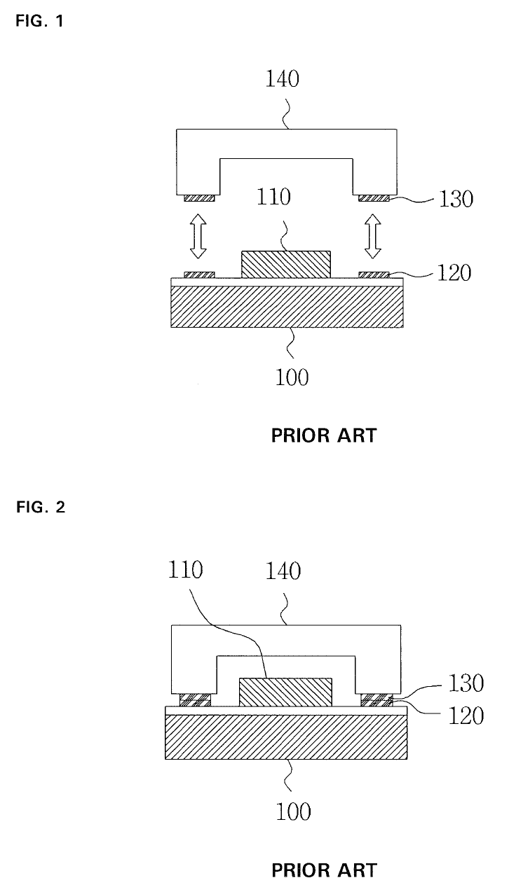

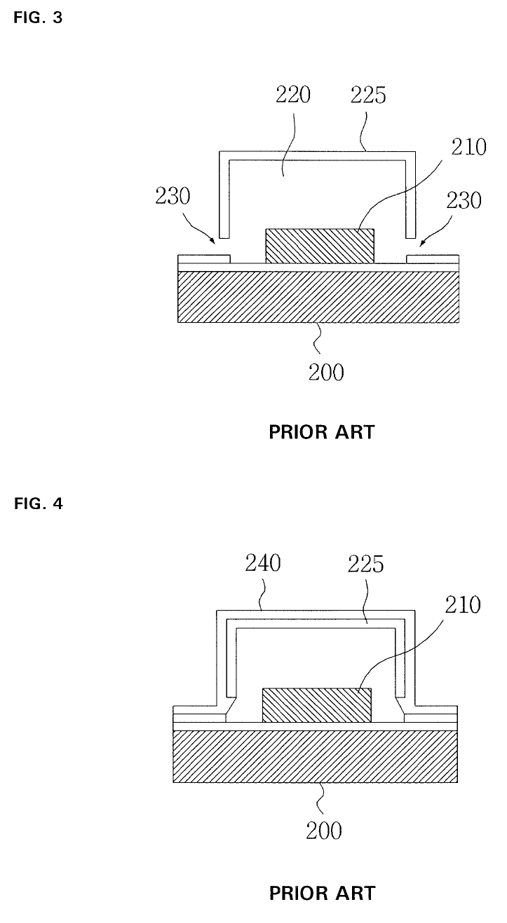

### DETAILED DESCRIPTION OF EXEMPLARY EMBODIMENTS

Hereinafter, a packaging method of a MEMS device in accordance with a preferred embodiment of the present invention will be described in detail referring to the accompanying drawings. The same reference numerals are used throughout the drawings to refer to the same or like parts. Detailed descriptions of well-known functions and structures incorporated herein may be omitted to avoid obscuring the subject matter of the present invention.

A packaging method of a MEMS switch device being an example of the MEMS device will be explained in an embodiment of the present invention.

### Manufacturing Method of a MEMS Switch Device

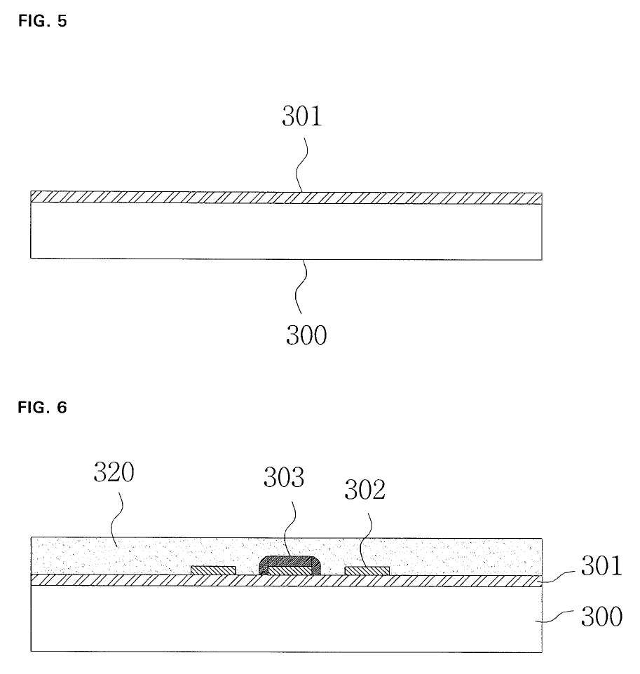

FIG. 5 to FIG. 9 are views illustrating a method for manufacturing a MEMS switch device in accordance with an embodiment of the present invention.

In the method for manufacturing an MEMS switch device, referring to FIG. 5, a first insulation layer 301 is deposited on a substrate 300. In this case, the first insulation layer 301 may be deposited on the substrate 300 using low-pressure chemical vapor deposition (LPCVD), plasma enhanced chemical vapor deposition (PECVD), or atmospheric pressure chemical vapor deposition (APCVD).

Next, referring to FIG. 6, a metal electrode layer 302, a second insulation layer 303, and a device sacrificial layer 320 are sequentially formed on the substrate 300. In this case, the device sacrificial layer 320 may be formed to comprise material consisting of metal or polymer.

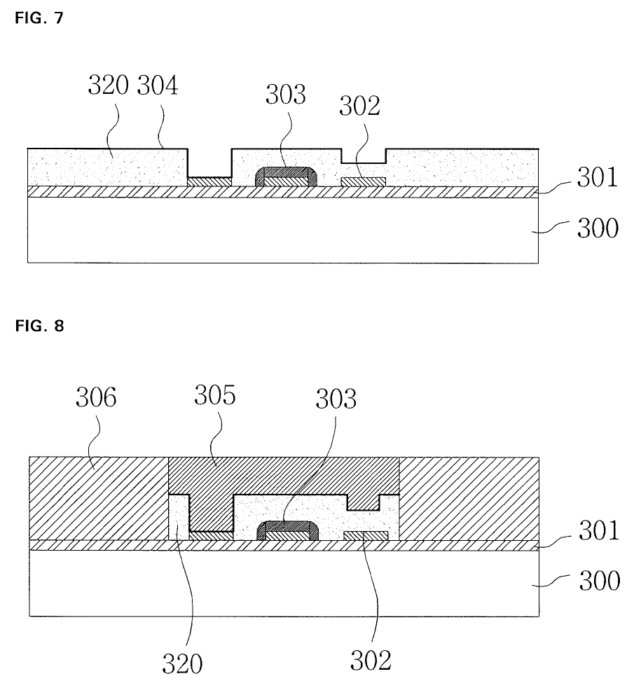

Subsequently, referring to FIG. 7, a partial region of the device sacrificial layer 320 is patterned in order to form a structure of a switch beam. On the patterned device sacrificial layer 320, a seed layer 304 is formed for plating a MEMS switch device.

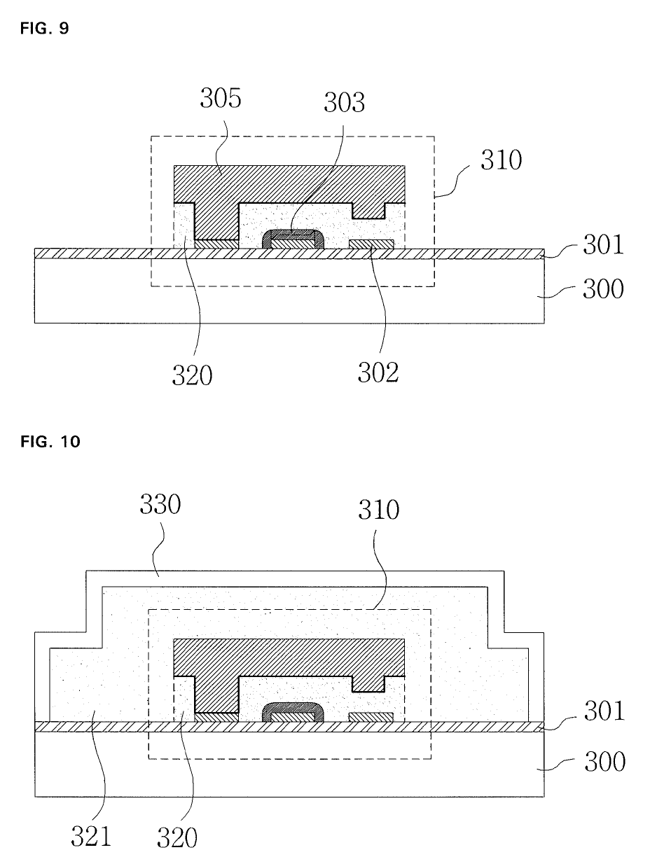

Next, referring to FIG. 8, a switch beam 305 is formed using photo-resist 306. As shown in FIG. 9, a MEMS switch device 310 is formed on the substrate 300. The device sacrificial layer 302 may be removed in a packaging process of a MEMS device to be described below.

A packaging method of a MEMS switch device in accordance with an embodiment of the present invention will be explained in detail by reference to the accompanying drawings hereinafter.

FIG. 10 to FIG. 17 are views illustrating a packaging method of a MEMS switch device in accordance with an embodiment of the present invention. The packaging method of a MEMS switch device in accordance with an embodiment of the present invention comprises the steps of: (a) forming a sacrificial layer 321 on a substrate 300 on which a MEMS switch device 310 is formed, forming a support layer 330 on the sacrificial layer 321, and forming a block copolymer layer 340 on the sacrificial layer 321; (b) self-assembling the block copolymer 340 on the sacrificial layer 321; (c) selectively etching a part of the self-assembled block copolymer layer 340 to form a plurality of nano-pores 343; (d) forming a plurality of etching holes 333 in the support layer 330 corresponding to the plurality of nano-pores 343 using the block copolymer layer 340 in which the plurality of nano-pores 343 are formed as mask; (e) removing the sacrificial layer 321 using the etching holes 333 formed in the support layer 330; and (f) forming a shielding layer 350 on the support layer 330.

Step (a)

In step (a), referring to FIG. 10, the sacrificial layer 321 is formed to cover the MEMS switch device 321 formed on the substrate 300. A deposition thickness of the sacrificial layer 321 can be adjusted according to a spacing distance between the MEMS switch device 321 and a packaged layer. The sacrificial layer 321 may be formed using metal or polymer. Copper may be used as the metal forming the sacrificial layer 321. Metal material is also selected and used in consideration of etching selectivity between the MEMS switch device 310 and the support layer 321 as the metal forming the sacrificial layer 321.

The support layer 330 is formed on the sacrificial layer 321. The support layer 330 may be formed comprising at least one of silicon oxide, a silicon oxide, and a silicon carbide, which have excellent mechanical strength.

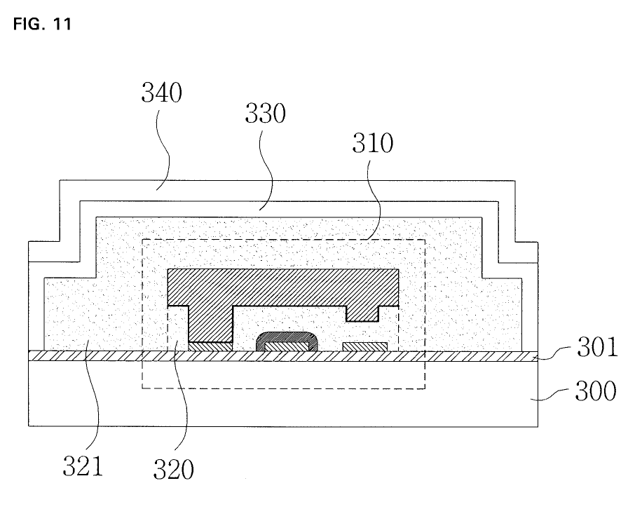

Subsequently, referring to FIG. 11, a block copolymer layer 340 is formed on the support layer 330. In this case, the block copolymer layer is a layer forming a polymer chain by a functional end part in which a monomer composed of different chemical components is formed by a covalent bond. Since the polymer chain has a low entropy for self-mixing, they are not mixed with each other. However, the polymer chain can be self-assembled to an assembled monomer having various nano-sized structures by bond features of the end part. There are PolyStyrene (PS), Poly(MethyMetAcrylate) (PMMA), Poly(Ethylene-alt-Propylene)(PEA), and Poly(VinylPyridine) (PVP) as examples of the assembled monomer.

Step (b)

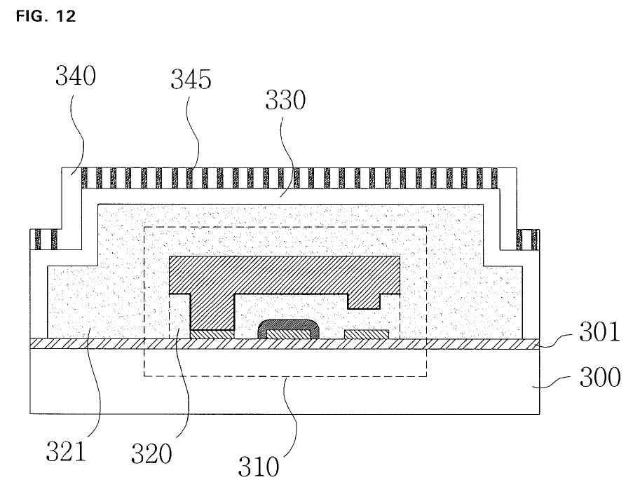

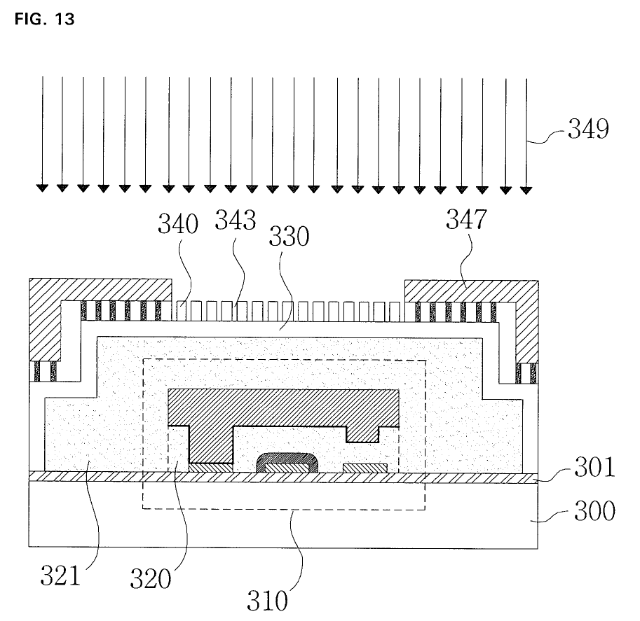

In step (b), the block copolymer 340 is spin-coated and undergoes a heat treatment at a temperature equal to or higher than 150° C. The heat treatment is performed at a temperature ranging from a glass transition point Tg of the block copolymer 340 to a melting point Tm thereof. A self-assembled structure can be classified into a sphere type, a cylinder type, a cut spiral type, and a layer type according to a mixing amount, molecular mass, surface energy, or bonding power of assembled monomers. Specific structures of an assembled monomer may be formed through a variety of factors such as a direction of the substrate 300, externally applied energy, and surface modification. In the embodiment of the present invention, the block copolymer layer 340 undergoes a heat treatment at a temperature ranging from about 200° C. to 250° C. Accordingly, referring to FIG. 12, an assembled monomer of the block copolymer layer 340 may be partially self-assembled to form a plurality of assembled monomers 345. In this case, the assembled monomers 345 may be a self-assembled nano-structure in which vertical cylinders are regularly arranged. Namely, in the embodiment of the present invention, the block copolymer layer 340 is most preferably PS-b-PMMA with a cylindrical structure of a large thickness.

Meanwhile, a diameter of the assembled monomers 345 and a spacing between the assembled monomers 345 can be adjusted according to molecular mass and a mixing amount of assembled monomers used in the block copolymer layer 340.

Step (c)

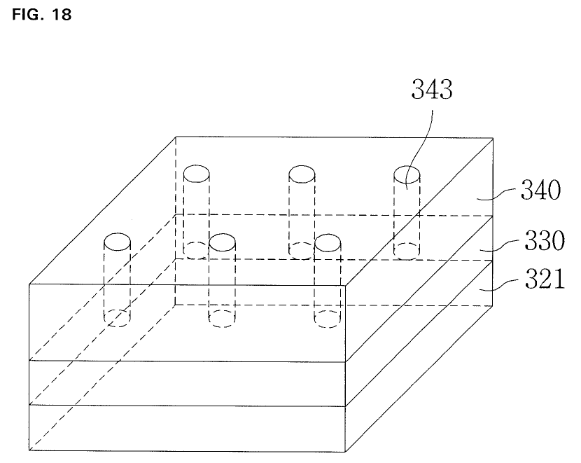

In step (c), referring to FIG. 13, a photo-resist 347 is patterned to expose a partial region of the block copolymer layer 340. Light 349 is irradiated on the exposed block copolymer layer 340 using the patterned photo-resist 347 as a mask. The assembled monomers 345 are disassembled due to the light irradiated to the block copolymer layer 340, whereas the block copolymer layer 340 region other than assembled monomers 345 is polymerized. A plurality of assembled monomers disassembled by the light are selectively removed to form a plurality of nano-pores 343. As a result, referring to FIG. 18, the plurality of nano-pores 343 with a vertically cylindrical structure are formed on the block copolymer layer 340.

Step (d)

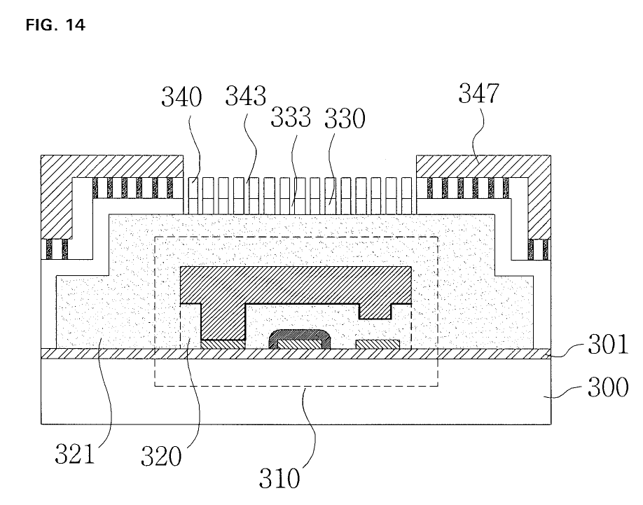

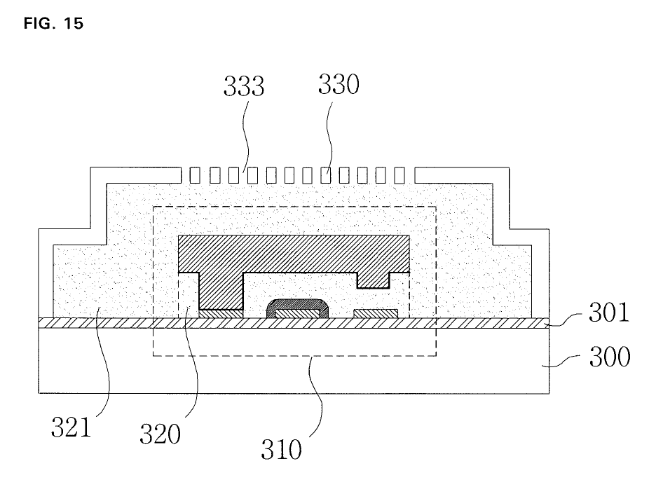

In step (d), a support layer 330 is selectively etched using the block copolymer layer 340 on which the plurality of nano-pores 343 are formed. Accordingly, referring to FIG. 14, a plurality of etching holes 333 are formed in the support layer 330 corresponding to the plurality of nano-pores 343. Subsequently, referring to FIG. 15, the photo-resist 347 and the block copolymer layer 340 are removed to expose all the etching holes 333 of the support layer 330.

Step (e)

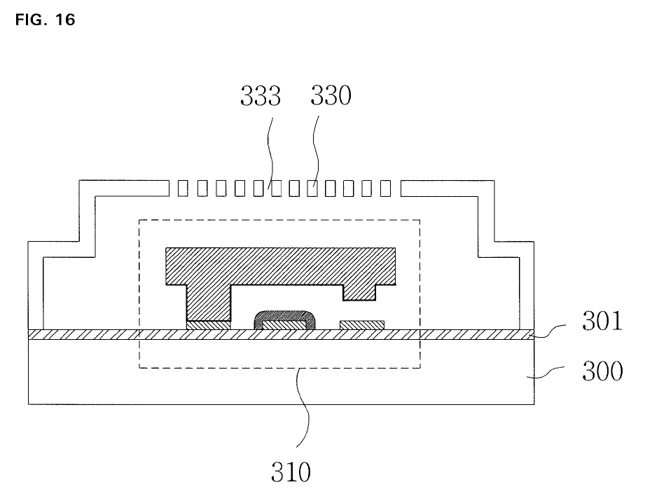

In step (e), referring to FIG. 16, a sacrificial layer 321 and the device sacrificial layer 320 remaining during a manufacturing process of the MEMS switch device 310 are removed through the etching holes formed in the support layer 330. Removal of the sacrificial layer 321 and the device sacrificial layer 320 can be carried out using the etching holes 333 by wet or dry etching. In this case, the sacrificial layer 321 and the device sacrificial layer 320 may be safely removed using the support layer 330 with excellent durability, wear resistance, and corrosion resistance.

Step (f)

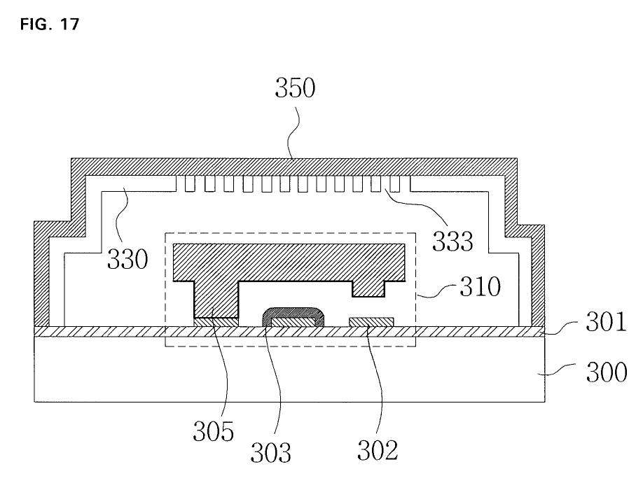

In step (f), referring to FIG. 17, a shielding layer 350 is formed on the support layer 300 for vacuum packaging of the MEMS switch device 310. The shielding layer 350 may be formed comprising at least one of a silicon oxide, a silicon nitride, and a silicon carbide. Because the silicon oxide, the silicon nitride, and the silicon carbide have excellent strength, when the shielding layer 350 is formed thereby, it can well resist pressure due to an atmosphere difference between a packaged inside and an outside thereof. Meanwhile, if the shielding layer 350 is formed by ion beam sputtering, various ceramic materials may be used besides the silicon carbide layer.

In the meantime, for adjusted atmosphere packaging, the support layer 330 may be coated with polymer materials such as benzocyclobutene (BCB) and polyimide under a desired atmosphere, and the resulting object undergoes a heat treatment to form the shielding layer 350. When the support layer 330 is coated with polymer materials with high viscosity, the polymer materials can penetrate between the etching holes 333 to more safely protect the MEMS switch device 310.

The details of a package of the MEMS switch device manufactured according to an embodiment of a packaging method of a MEMS device of the present invention is seen with reference to the accompanying drawings.

FIG. 17 is a view illustrating a package of a MEMS switch device in accordance with an embodiment of the present invention.

The package of a MEMS switch device in accordance with an embodiment of the present invention includes a MEMS switch device 310, a support layer 330, and a shielding layer 350.

A first insulation layer 301 is formed on a substrate 300. In this case, the MEMS switch device 310 is formed on the first insulation layer 301. The MEMS switch device 310 comprises a plurality of metal electrode layers 302, a MEMS switch beam 305 performing a switching operation through the metal electrode layers 302, and a second insulation layer 303 formed on the metal electrode layer to be spaced apart from the MEMS switch beam 305.

The support layer 330 is formed to enclose the MEMS switch device 310 formed on the substrate 300. The support layer 330 is spaced apart from the MEMS switch device 310 by a predetermined distance so that a fluidized space of the MEMS switch beam 305 may be secured. A plurality of nano-sized etching holes 333 are formed in an upper portion of the support layer 330. The support layer 330 comprises at least one of a silicon oxide, a silicon nitride, and a silicon carbide with excellent mechanical strength.

The shielding layer 350 is formed to enclose the support layer 330. The shielding layer 350 functions to seal an inside of the support layer 330 in a vacuum or gas state. The shielding layer 350 comprises at least one of a silicon oxide, a silicon nitride, and a silicon carbide. Since the silicon oxide, the silicon nitride, and the silicon carbide have excellent mechanical strength, it can well resist pressure due to an atmosphere difference between an inside to which the MEMS switch device 310 is packaged and an outside thereof. In a case of an adjusted atmosphere package,

the shielding layer 350 can be formed to include at least one of benzocyclobutene (BCB) and polyimide.

Although embodiments in accordance with the present invention have been described in detail hereinabove, it should be understood that many variations and modifications of the basic inventive concept herein described, which may appear to those skilled in the art, will still fall within the spirit and scope of the exemplary embodiments of the present invention as defined in the appended claims.

What is claimed is:

1. A packaging method of a micro electro mechanical system (MEMS) device comprising:
(a) sequentially forming a sacrificial layer, a support layer, and a block copolymer layer on a substrate on which the micro electro mechanical system device is formed;
(b) self-assembling the block copolymer layer formed on the support layer;
(c) selectively etching a part of the self-assembled block copolymer layer to form a plurality of nano-pores;
(d) forming a plurality of etching holes in the support layer corresponding to the plurality of nano-pores using the block copolymer layer in which the plurality of nano-pores are formed as a mask;
(e) removing the sacrificial layer using the etching holes formed in the support layer; and
(f) forming a shielding layer on the support layer.

2. The packaging method according to claim 1, further comprising removing the block copolymer layer in which the plurality of nano-pores are formed after step (d).

3. The packaging method according to claim 1, wherein the sacrificial layer is formed to comprise material consisting of metal or polymer.

4. The packaging method according to claim 1, wherein the support layer is formed to comprise at least one of a silicon oxide, a silicon nitride, and a silicon carbide.

5. The packaging method according to claim 1, wherein step (b) comprises:
spin-coating the block copolymer layer formed on the support layer; and
heating treat the spin-coated block copolymer layer to self-assembling the block copolymer layer so that a plurality of assembled monomers with a cylindrical structure are formed.

6. The packaging method according to claim 5, wherein step (c) comprises:
patterning a photo-resist to expose a partial region of the block copolymer layer;
irradiating light on the exposed block copolymer layer using the photo-resist as a mask; and
removing the plurality of assembled monomers with the cylindrical structure from the block copolymer layer to the light is irradiated.

7. The packaging method according to claim 1, wherein the shielding layer is formed to comprise at least one of a silicon oxide, a silicon nitride, and a silicon carbide.

8. The packaging method according to claim 1, wherein the shielding layer is formed to comprise at least one of benzocyclobutene (BCB) and polyimide.

9. A package of a micro electro mechanical system (MEMS) device comprising:
a micro electro mechanical system device formed on a substrate;
a support layer being spaced apart from the micro electro mechanical system device formed on the substrate to enclose the micro electro mechanical system device wherein a plurality of etching holes are formed in an upper portion of the support layer; and
a shielding layer formed to enclose the support layer.

10. The package according to claim 9, wherein the support layer comprises at least one of a silicon oxide, a silicon nitride, and a silicon carbide.

11. The package according to claim 9, wherein the shielding layer comprises at least one of a silicon oxide, a silicon nitride, and a silicon carbide.

12. The package according to claim 9, wherein the shielding layer comprises at least one of benzocyclobutene (BCB) and polyimide.
